(19) United States
(12) Patent Application Publication
(10) Pub. No.: US 2025/0372186 A1
(43) Pub. Date: Dec. 4, 2025

(54) MEMORY DEVICE FOR PERFORMING PROGRAM OPERATION AND METHOD OF OPERATING THE SAME

(71) Applicant: SK hynix Inc., Gyeonggi-do (KR)

(72) Inventor: Ji Hyun LEE, Gyeonggi-do (KR)

(21) Appl. No.: 18/963,759

(22) Filed: Nov. 29, 2024

(30) Foreign Application Priority Data
May 29, 2024 (KR) 10-2024-0070172

(51) Int. Cl. G11C 16/34; G11C 16/08

(52) U.S. Cl. CPC G11C 16/3459; G11C 16/08; G11C 16/3404

(57) ABSTRACT

A memory device may include a memory cell array including a plurality of memory cells connected to word lines and bit lines, a peripheral circuit configured to perform a first program voltage apply operation of increasing threshold voltages of selected memory cells and a verify operation of verifying program states of the selected memory cells based on the increased threshold voltages, and a control logic configured to, after the verify operation has succeeded, control the peripheral circuit to determine a bit line voltage by which a bit line connected to the memory cell having succeeded in a verify operation is precharged, based on threshold voltages of memory cells connected to one or more adjacent word lines, and perform a second program voltage apply operation of increasing a threshold voltage of the memory cell having succeeded in the verify operation based on determined bit line voltage.

### CROSS-REFERENCE TO RELATED APPLICATION

The present application claims priority under 35 U.S.C. § 119 (a) to Korean patent application number 10-2024-0070172 filed on May 29, 2024, the entire disclosure of which is incorporated by reference herein.

### BACKGROUND

### 1. Field of Invention

Various embodiments of the present disclosure generally relate to a semiconductor device, and more particularly to a memory device for performing a program operation and a method of operating the memory device.

### 2. Description of Related Art

Memory devices may be devices in which data is stored, and may be classified into volatile memory devices and nonvolatile memory devices.

Such a memory device may perform a program operation of storing data in memory cells. The reliability of a memory device may be improved as the state in which the threshold voltage distribution of memory cells formed by the program operation is narrow and is maintained for a longer time.

Ater the program operation is completed, the threshold voltage distribution of the memory cells may change due to short time retention. In this case, since the reliability of the memory device may be decreased, a scheme capable of compensating for the decrease in reliability is required.

### SUMMARY

Various embodiments of the present disclosure are directed to a memory device and a method of operating the memory device, which is capable of improving reliability.

An embodiment of the present disclosure may provide for a memory device. The memory device may include a memory cell array including a plurality of memory cells connected to a plurality of word lines and a plurality of bit lines, a peripheral circuit configured to perform a first program voltage apply operation of increasing threshold voltages of selected memory cells connected to a selected word line, among the plurality of memory cells and a verify operation of verifying program states of the selected memory cells based on the increased threshold voltages, and a control logic configured to, after the verify operation performed on at least one of the selected memory cells has succeeded, control the peripheral circuit to determine, based on threshold voltages of memory cells connected to one or more word lines adjacent to the selected word line among the plurality of memory cells, a bit line voltage by which a bit line connected to the memory cell having succeeded in the verify operation among the plurality of bit lines is to be precharged, and perform a second program voltage apply operation of increasing a threshold voltage of the memory cell having succeeded in the verify operation based on the determined bit line voltage.

An embodiment of the present disclosure may provide for a method of operating a memory device including a plurality of memory cells connected to a plurality of word lines and a plurality of bit lines. The method may include increasing threshold voltages of selected memory cells connected to a selected word line, among the plurality of memory cells, verifying program states of the selected memory cells, determining, in response to a determination that an operation of verifying the program state of at least one of the selected memory cells has succeeded, a bit line voltage by which a bit line connected to the memory cell having succeeded in the verify operation among the plurality of bit lines is to be precharged, based on threshold voltages of memory cells connected to one or more word lines adjacent to the selected word line among the plurality of memory cells, precharging the bit line connected to the memory cell having succeeded in the verify operation to the determined bit line voltage, and increasing a threshold voltage of the memory cell having succeeded in the verify operation.

An embodiment of the present disclosure may provide for a memory device. The memory device may include a memory cell array including a plurality of memory cells connected to a plurality of word lines, a peripheral circuit configured to perform a first program operation including a plurality of program loops, each of the plurality of program loop including a program voltage apply operation of increasing threshold voltages of selected memory cells connected to a selected word line among the plurality of memory cells and a verify operation of verifying program states of the selected memory cells based on the increased threshold voltages, and a control logic configured to, when the verify operation performed on at least one of the selected memory cells has succeeded in a first program loop among the plurality of program loops, control the peripheral circuit to determine a bit line voltage by which a bit line connected to the memory cell having succeeded in the verify operation included in the first program loop among the plurality of bit lines is to be precharged, based on threshold voltages of memory cells connected to one or more word lines adjacent to the selected word line among the plurality of memory cells in a second program loop performed after the first program loop among the plurality of program loops, and perform the program voltage apply operation of increasing a threshold voltage of the memory cell having succeeded in the verify operation included in the first program loop based on the determined bit line voltage.

### BRIEF DESCRIPTION OF THE DRAWINGS

FIG. 1 is a diagram illustrating a memory device according to an embodiment of the present disclosure.

FIG. 2 is a diagram illustrating a program operation according to an embodiment of the present disclosure.

FIG. 3 is a diagram for describing the threshold voltage distribution of memory cells formed by a program operation according to an embodiment of the present disclosure.

FIG. 4 is a diagram illustrating the order of performance of a first program operation and a second program operation according to an embodiment of the present disclosure.

FIGS. 5A and 5B are diagrams for describing threshold voltage distribution changes due to short time retention according to an embodiment of the present disclosure.

FIG. 6 is a diagram for describing an over-program operation according to an embodiment of the present disclosure.

FIG. 7 is a diagram for describing bit line voltages to which bit lines are precharged during an over-program operation according to an embodiment of the present disclosure.

FIG. 8 is a flowchart illustrating a method of operating a memory device according to an embodiment of the present disclosure.

### DETAILED DESCRIPTION

Specific structural or functional descriptions in the embodiments of the present disclosure introduced in this specification are provided as examples to describe embodiments according to the concept of the present disclosure. The embodiments according to the concept of the present disclosure may be practiced in various forms, and should not be construed as being limited to the embodiments described in the specification.

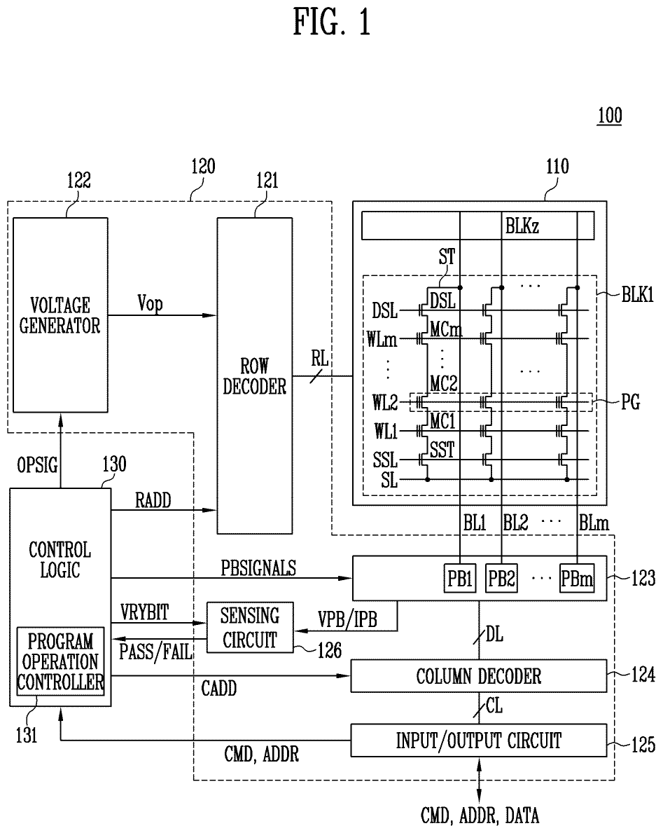

FIG. 1 is a diagram illustrating a memory device 100 according to an embodiment of the present disclosure.

Referring to FIG. 1, the memory device 100 may include a memory cell array 110, a peripheral circuit 120, and a control logic 130.

The memory cell array 110 may include a plurality of memory blocks BLK1 to BLKz.

The plurality of memory blocks BLK1 to BLKz may be connected to a row decoder 121 through row lines RL. Here, the row lines RL may include at least one source select line SSL, a plurality of word lines WL1 to WLm, and at least one drain select line DSL.

Each of the memory blocks BLK1 to BLKz may include a plurality of memory cells MC1 to MCm. The plurality of memory cells MC1 to MCm may be connected to a page buffer group 123 through a plurality of bit lines BL1 to BLm. Each of the plurality of memory blocks BLK1 to BLKz may include a plurality of memory cell strings ST connected between the bit lines BL1 to BLm and a source line SL. Each of the memory cell strings ST may include at least one source select transistor SST, a plurality of memory cells MC1 to MCm, and at least one drain select transistor DST which are connected in series to each other between the source line SL and a corresponding one of the bit lines BL1 to BLm.

Each of the plurality of memory cells MC1 to MCm may be connected to one of the plurality of word lines WL1 to WLm. Memory cells connected to the same word line may be defined as one page PG. Each of the memory cells MC1 to MCm may store a plurality of data bits.

The peripheral circuit 120 may perform a program operation, a read operation, or an erase operation on a selected area of the memory cell array 110 under the control of the control logic 130.

The peripheral circuit 120 may include the row decoder 121, a voltage generator 122, the page buffer group 123, a column decoder 124, an input/output circuit 125, and a sensing circuit 126.

The row decoder 121 may decode a row address RADD received from the control logic 130. The row decoder 121 selects at least one of the memory blocks BLK1 to BLKz according to the decoded address. Further, the row decoder 121 may select at least one word line of the memory block selected according to the decoded address. The row decoder 121 may apply voltages Vop generated by the voltage generator 122 to the selected word line.

The voltage generator 122 may generate a plurality of voltages using an external supply voltage provided to the memory device 100. In detail, the voltage generator 122 may generate various operating voltages Vop that are used for program, read, and erase operations in response to an operation signal OPSIG. The plurality of generated voltages Vop may be supplied to the memory cell array 110 by the row decoder 121.

The page buffer group 123 may include a plurality of page buffers PB1 to PBm. The plurality of page buffers PB1 to PBm may temporarily store data received through the plurality of bit lines BL1 to BLm or sense the voltages or currents of the plurality of bit lines BL1 to BLm during a read or verify operation in response to page buffer control signals PBSIGNALS.

The column decoder 124 may transfer data between the input/output circuit 125 and the page buffer group 123 in response to a column address CADD.

The input/output circuit 125 may transmit a command CMD and an address ADDR, received from a memory controller (not illustrated), to the control logic 130, or may exchange data DATA with the column decoder 124.

The sensing circuit 126 may determine whether a verify operation for a specific program state has passed with the application of a verify voltage.

In an embodiment, the sensing circuit 126 may perform a check operation of determining whether the verify operation has passed based on data sensed from the plurality of memory cells MC1 to MCm while a program voltage is applied to a word line.

In an example, during the verify operation, the sensing circuit 126 may generate a reference current in response to an enable bit signal VRYBIT, and may compare a sensing voltage VPB received from the page buffer group 123 with a reference voltage generated by the reference current and then output a pass signal PASS or a fail signal FAIL. In an example, during the verify operation, the sensing circuit 126 may generate a reference voltage in response to the enable bit signal VRYBIT, and may compare a sensing current IPB received from the page buffer group 123 with a reference current generated by the reference voltage and then output a pass signal PASS or a fail signal FAIL.

The control logic 130 may control the peripheral circuit 120 by outputting the operation signal OPSIG, the row address RADD, and the page buffer control signals PBSIGNALS in response to the command CMD and the address ADDR.

In an embodiment, the control logic 130 may include a program operation controller 131.

The program operation controller 131 may control a program operation of the memory device 100. For example, the program operation controller 131 may provide the operation signal OPSIG for controlling the generation of a program voltage Vpgm, a verify voltage Vvfy, etc. to the voltage generator 122, and may generate a row address RADD by decoding the address ADDR of a word line in which data DATA is to be stored.

In an embodiment, the program operation controller 131 may perform a program operation on selected memory cells connected to a selected word line, among the plurality of memory cells MC1 to MCm. For example, the program operation controller 131 may increase the threshold voltages of the selected memory cells by applying the program voltage to the selected word line among the plurality of word lines WL1 to WLm, and may verify the program states of the selected memory cells.

In an embodiment, when the verify operation performed on the selected memory cells has succeeded, the program operation controller 131 may control the peripheral circuit 120 to increase again the threshold voltages of the memory cells having succeeded in the verify operation. For example, the program operation controller 131 may determine a bit line voltage based on the threshold voltages of memory cells connected to one or more word lines adjacent to the selected word line, among the plurality of memory cells MC1 to MCm. The program operation controller 131 may precharge the bit lines connected to the memory cells having succeeded in the verify operation, among the plurality of bit lines BL1 to BLm, to the determined bit line voltage, and thereafter apply the program voltage to the selected word line, thus increasing the threshold voltages of the memory cells having succeeded in the verify operation.

Therefore, according to an embodiment of the present disclosure, changes in the threshold voltage distribution of the memory cells to be caused by short time retention may be compensated for by performing an over-program operation of increasing again the threshold voltages of memory cells having succeeded in the verify operation, thus improving the reliability of the memory device 100. Hereinafter, embodiments in which an over-program operation is performed will be described in detail.

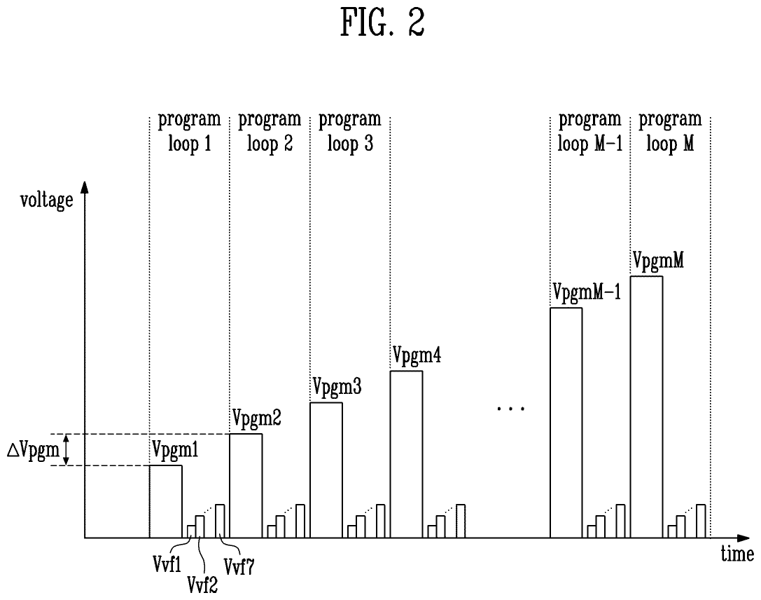

FIG. 2 is a diagram illustrating a program operation according to an embodiment of the present disclosure.

Referring to FIG. 2, the program operation may include a plurality of program loops. Each program loop may include a program voltage apply operation of applying a program voltage to a selected word line and a verify operation of verifying program states of selected memory cells. The program voltage apply operation may be an operation of increasing the threshold voltage of each memory cell, and the verify operation may be an operation of determining the threshold voltage and then verifying whether the corresponding memory cell has reached a target program state. For example, a first program loop may include an operation of applying a first program voltage Vpgm1 and a plurality of main verify voltages Vvf1 to Vvf7 to the selected word line. Although, for convenience of description, seven main verify voltages are illustrated as being applied in all program loops, the number of verify voltages is not limited thereto, and different main verify voltages and pre-verify voltages may be applied.

The voltage generator 122 may increase the program voltage by a unit voltage AVpgm as program loops are sequentially performed. This scheme is referred to as an incremental step pulse programming (ISPP) scheme. For example, the voltage generator 122 may generate a second program voltage Vpgm2 higher than the first program voltage Vpgm1 by the unit voltage AVpgm in a second program loop. For convenience of description, the unit voltage is illustrated as being fixed, but the unit voltage may be dynamically changed.

In an embodiment, the control logic 130 may set a memory cell, having reached a target program state while M program loops are being performed, to a program-inhibit state so that programming is no longer performed on the memory cell. Even if a subsequent program loop is performed, the threshold voltage of the memory cell that enters the program-inhibit state may be maintained. For example, the control logic 130 may set a memory cell, on which programming to a second program state P2 that is the target program state has been completed in the second program loop, to a program-inhibit state. In an embodiment, the bit line of the memory cell having reached the target program state may be precharged by a program-inhibit voltage. When the bit line is precharged to the program-inhibit voltage, the channel of the memory cell may be self-boosted by the program voltage, and the memory cell may not be programmed.

In an embodiment, for the memory cell having reached the target program state while M program loops are being performed, the control logic 130 may increase the threshold voltage of the corresponding memory cell once more in a subsequent program loop, and may then set the corresponding memory cell to a program-inhibit state. For example, the control logic 130 may increase the threshold voltage of a memory cell, on which programming to the second program state P2 that is the target program state has been completed in the second program loop, once more in a third program loop, and may then set the memory cell to a program-inhibit state.

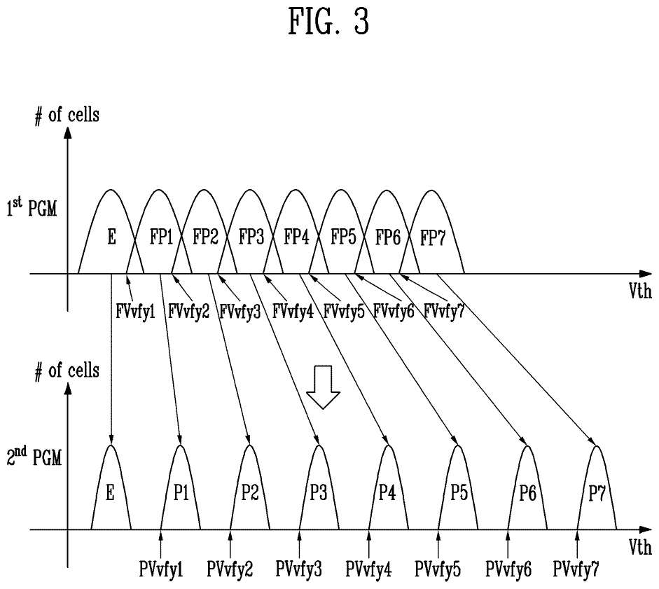

FIG. 3 is a diagram for describing the threshold voltage distribution of memory cells formed by a program operation according to an embodiment of the present disclosure. In an embodiment of the present disclosure, the threshold voltage distribution of memory cells programmed according to a triple-level cell (TLC) scheme will be described by way of example.

Referring to FIG. 3, the control logic 130 may control the peripheral circuit 120 to program data by performing a first program operation (1^{st} PGM) on the memory cells. Thereafter, the control logic 130 may control the peripheral circuit 120 to reprogram data by performing a second program operation (2^{nd} PGM) on the memory cells. In an embodiment, the first program operation (1^{st} PGM) may be referred to as a foggy program operation, and the second program operation (2^{nd} PGM) may be referred to as a fine program operation. In an embodiment, each of the first program operation (1^{st} PGM) and the second program operation (2^{nd} PGM) may include a plurality of program loops illustrated in FIG. 2.

The threshold voltage distribution of memory cells programmed depending on the first program operation (1^{st} PGM) may be wider than the threshold voltage distribution of memory cells programmed depending on the second program operation (2^{nd} PGM).

The first program operation (1^{st} PGM) may be an operation of programming the memory cells so that the memory cells have threshold voltages corresponding to an erase state E and first to seventh foggy program states FP1 to FP7. The first program operation (1^{st} PGM) may be an operation using first to seventh foggy verify voltages FVvfy1 to FVvfy7 respectively corresponding to the first to seventh foggy program states FP1 to FP7.

The second program operation (2^{nd} PGM) may be an operation in which the memory cells have threshold voltages corresponding to the erase state E and first to seventh program states P1 to P7. The second program operation (2^{nd} PGM) may be an operation using first to seventh fine verify voltages PVvfy1 to PVvfy7 respectively corresponding to the first to seventh program states P1 to P7.

Each of the memory cells may have one of the erase state E and the first to seventh program states P1 to P7, which are the fine program states, as the target program state. The target program state may be determined depending on data to be stored in each memory cell.

In detail, among the memory cells, memory cells having the erase state E as the target program state may have threshold voltages corresponding to the erase state E through the first program operation (1^{st} PGM). Also, the corresponding memory cells may have threshold voltages corresponding to the erase state E through the second program operation (2^{nd} PGM).

Further, among the memory cells, memory cells having the first program state P1 as the target program state may have threshold voltages corresponding to the first foggy program state FP1 through the first program operation (1^{st} PGM). Also, the corresponding memory cells may have threshold voltages corresponding to the first program state P1 through the second program operation (2^{nd} PGM).

Furthermore, among the memory cells, memory cells having the second program state P2 as the target program state may have threshold voltages corresponding to the second foggy program state FP2 through the first program operation (1^{st} PGM). Also, the corresponding memory cells may have threshold voltages corresponding to the second program state P2 through the second program operation (2^{nd} PGM).

Furthermore, among the memory cells, memory cells having the third program state P3 as the target program state may have threshold voltages corresponding to the third foggy program state FP3 through the first program operation (1^{st} PGM). Also, the corresponding memory cells may have threshold voltages corresponding to the third program state P3 through the second program operation (2^{nd} PGM).

Furthermore, among the memory cells, memory cells having the fourth program state P4 as the target program state may have threshold voltages corresponding to the fourth foggy program state FP4 through the first program operation (1^{st} PGM). Also, the corresponding memory cells may have threshold voltages corresponding to the fourth program state P4 through the second program operation (2^{nd} PGM).

Furthermore, among the memory cells, memory cells having the fifth program state P5 as the target program state may have threshold voltages corresponding to the fifth foggy program state FP5 through the first program operation (1^{st} PGM). Also, the corresponding memory cells may have threshold voltages corresponding to the fifth program state P5 through the second program operation (2^{nd} PGM).

Furthermore, among the memory cells, memory cells having the sixth program state P6 as the target program state may have threshold voltages corresponding to the sixth foggy program state FP6 through the first program operation (1^{st} PGM). Also, the corresponding memory cells may have threshold voltages corresponding to the sixth program state P6 through the second program operation (2^{nd} PGM).

Furthermore, among the memory cells, memory cells having the seventh program state P7 as the target program state may have threshold voltages corresponding to the seventh foggy program state FP7 through the first program operation (1^{st} PGM). Also, the corresponding memory cells may have threshold voltages corresponding to the seventh program state P7 through the second program operation (2^{nd} PGM).

Although the memory cells of FIG. 3 are illustrated as having threshold voltages corresponding to one of the erase state E and the first to seventh foggy program states FP1 to FP7 through the first program operation (1^{st} PGM), the embodiments of the present disclosure are not limited thereto. For example, the first program operation (1^{st} PGM) may be an operation of programming the memory cells so that the memory cells have threshold voltages corresponding to one state among the erase state E and one or more foggy program states. In this case, the number of one or more foggy program states may be less than 7.

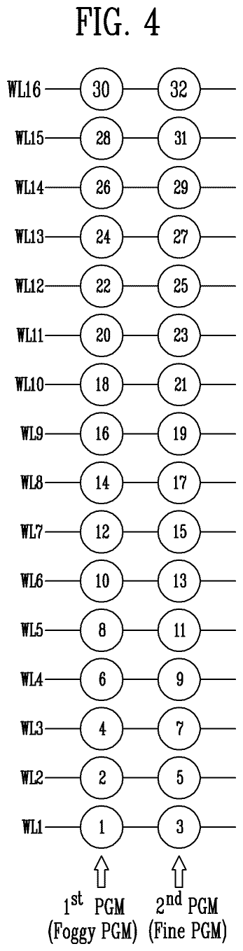

FIG. 4 is a diagram illustrating the order of performance of a first program operation and a second program operation according to an embodiment of the present disclosure. For convenience of description, only first to sixteenth word lines WL1 to WL16 among a plurality of word lines WL1 to WLm are illustrated.

Referring to FIG. 4, the order in which the first program operation (1^{st} PGM) and the second program operation (2^{nd} PGM) are performed on memory cells connected to the first to sixteenth word lines WL1 to WL16 is indicated by numbers in circles. In order to minimize the influence of program disturb on memory cells connected to one or more word lines adjacent to the selected word line during the second program operation (2^{nd} PGM) on the selected memory cells, the order of all program operations may be determined such that, after the first program operation (1^{st} PGM) on the memory cells connected to the one or more adjacent word lines is completed, the second program operation (2^{nd} PGM) is performed on the corresponding memory cells.

The peripheral circuit 120 may firstly perform a first program operation (1^{st} PGM) on memory cells connected to the first word line WL1. Thereafter, the peripheral circuit 120 may secondly perform a first program operation (1^{st} PGM) on memory cells connected to the second word line WL2. Thereafter, the peripheral circuit 120 may thirdly perform a second program operation (2^{nd} PGM) on the memory cells connected to the first word line WL1 adjacent to the second word line WL2.

Subsequently, the peripheral circuit 120 may fourthly perform a first program operation (1^{st} PGM) on memory cells connected to the third word line WL3 adjacent to the second word line WL2, and may fifthly perform a second program operation (2^{nd} PGM) on the memory cells connected to the second word line WL2. When this process is generalized, it can be seen that, for a natural number i equal to or greater than 1, a first program operation (1^{st} PGM) is performed on memory cells connected to an (i+1)-th word line WLi+1 before a second program operation (2^{nd} PGM) is performed on memory cells connected to the i-th word line WLi.

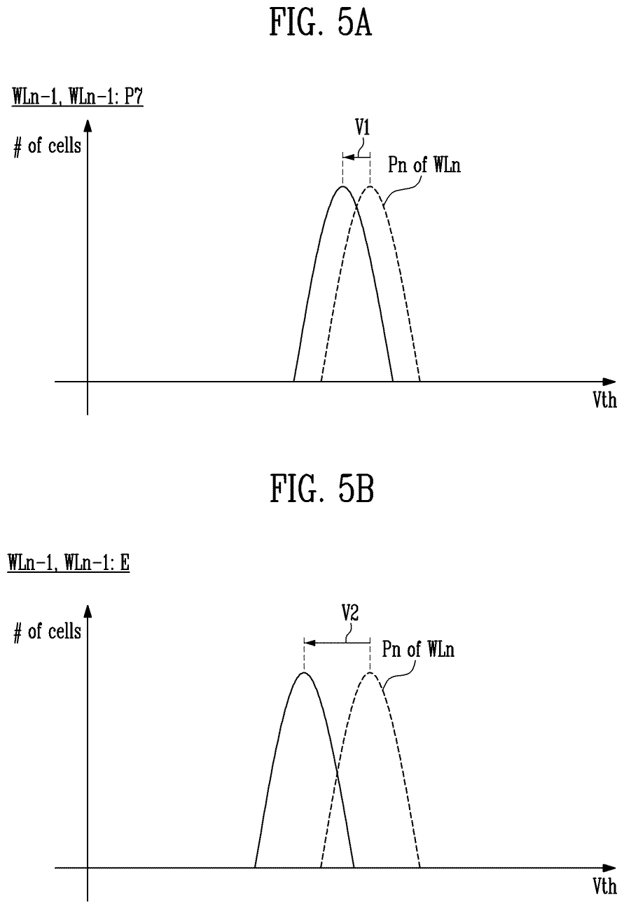

FIGS. 5A and 5B are diagrams for describing threshold voltage distribution changes due to short time retention according to an embodiment of the present disclosure. In detail, FIG. 5A is a diagram for describing changes to the threshold voltage distribution Pn of selected memory cells connected to a selected word line WLn when the threshold voltage distributions of adjacent memory cells connected to adjacent word lines WLn−1 and WLn+1 correspond to a seventh program state P7. FIG. 5B is a diagram for describing changes to the threshold voltage distribution Pn of selected memory cells connected to a selected word line WLn when the threshold voltage distributions of the memory cells connected to adjacent word lines WLn−1 and WLn+1 correspond to an erase state E. The horizontal axis of graphs illustrated in FIGS. 5A and 5B may denote the magnitude of voltage, and the vertical axis of the graphs may denote the number of selected memory cells.

Referring to FIG. 5A, the threshold voltage distribution Pn of the selected memory cells may change due to short time retention immediately after a program operation performed on the selected memory cells is completed. For example, when the threshold voltage distributions of the adjacent memory cells correspond to the seventh program state P7, the threshold voltage distribution Pn of the selected memory cells may be decreased by the magnitude of a first voltage V1.

Referring to FIG. 5B, when the threshold voltage distributions of the adjacent memory cells correspond to the erase state E, the threshold voltage distribution Pn of the selected memory cells may be decreased by the magnitude of a second voltage V2.

In this case, the magnitude of the second voltage V2 may be greater than the magnitude of the first voltage V1. That is, as the threshold voltage distributions of the adjacent memory cells are lower, the change in the threshold voltage distribution Pn of the selected memory cells attributable to short time retention may be greater.

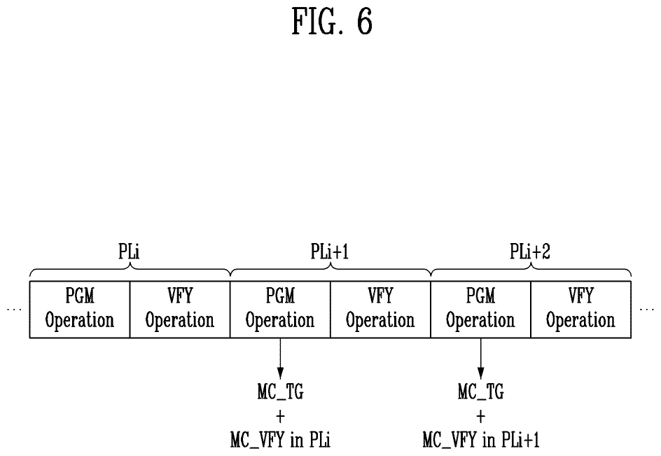

FIG. 6 is a diagram for describing an over-program operation according to an embodiment of the present disclosure. i-th to (i+2)-th program loops PLi to PLi+2 illustrated in FIG. 6 may correspond to some of the plurality of program loops illustrated in FIG. 2.

Referring to FIG. 6, the control logic 130 may control the peripheral circuit 120 to perform a program voltage apply operation on memory cells having succeeded in a verify operation (VFY Operation), based on the threshold voltages of memory cells connected to one or more word lines adjacent to a selected word line after the verify operation (VFY Operation) on selected memory cells has succeeded.

For example, the peripheral circuit 120 may perform a program voltage apply operation (PGM Operation) and a verify operation (VFY Operation) on the selected memory cells in the i-th program loop PLi.

Further, the peripheral circuit 120 may perform an (i+1)-th program loop PLi+1 after the i-th program loop PLi. When the verify operation (VFY Operation) on one or more memory cells among the selected memory cells has succeeded in the i-th program loop PLi, the control logic 130 may control the peripheral circuit 120 to perform a program voltage apply operation (PGM Operation) on target memory cells MC_TG and memory cells MC VFY, having succeeded in the verify operation (VFY Operation) in the i-th program loop PLi, in the (i+1)-th program loop PLi+1. Here, the target memory cells MC_TG may refer to memory cells having failed in the verify operation (VFY Operation) in the i-th program loop PLi.

In an embodiment, the control logic 130 may set the memory cells MC_VFY, having succeeded in the verify operation (VFY Operation) in the i-th program loop PLi, to program-inhibit cells after the program voltage apply operation (PGM Operation) in the (i+1)-th program loop PLi+1.

Also, the control logic 130 may control the peripheral circuit 120 to perform the verify operation (VFY Operation) on the target memory cells MC_TG in the (i+1)-th program loop PLi+1. In an embodiment, the control logic 130 may skip the verify operation (VFY Operation) in the (i+1)-th program loop PLi+1 on the memory cells MC_VFY having succeeded in the verify operation (VFY Operation) in the i-th program loop PLi.

Further, the peripheral circuit 120 may perform an (i+2)-th program loop PLi+2 after the (i+1)-th program loop PLi+1. When the verify operation (VFY Operation) on one or more memory cells among the target memory cells MC_TG in the (i+1)-th program loop PLi+1 has succeeded, the control logic 130 may control the peripheral circuit 120 to perform a program voltage apply operation (PGM Operation) on target memory cells MC_TG and memory cells MC VFY, having succeeded in the verify operation (VFY Operation) in the (i+1)-th program loop PLi+1, in the (i+2)-th program loop PLi+2. Here, the target memory cells MC_TG may refer to memory cells having failed in the verify operation (VFY Operation) in the (i+1)-th program loop PLi+1. Moreover, because the memory cells MC_VFY having succeeded in the verify operation (VFY Operation) in the i-th program loop PLi are set to program-inhibit cells, they may be excluded from the program voltage apply operation (PGM Operation) in the (i+2)-th program loop PLi+2.

In an embodiment, the control logic 130 may set a memory cell MC_VFY, having succeeded in the verify operation (VFY Operation) in the (i+1)-th program loop PLi+1, to a program-inhibit cell after the program voltage apply operation (PGM Operation) in the (i+2)-th program loop PLi+2.

Furthermore, the control logic 130 may control the peripheral circuit 120 to perform a verify operation (VFY Operation) on the target memory cells MC_TG in the (i+2)-th program loop PLi+2. In an embodiment, the control logic 130 may skip the verify operation (VFY Operation) in the (i+2)-th program loop PLi+2 on the memory cell MC_VFY having succeeded in the verify operation (VFY Operation) in the (i+1)-th program loop PLi+1.

In an embodiment, the control logic 130 may perform an over-program operation during a fine program operation performed on the selected memory cells. For example, when the verify operation (VFY Operation) on the selected memory cells has succeeded during the fine program operation, the control logic 130 may control the peripheral circuit 120 to perform a program voltage apply operation on the memory cells having succeeded in the verify operation (VFY Operation) based on the threshold voltages of adjacent memory cells.

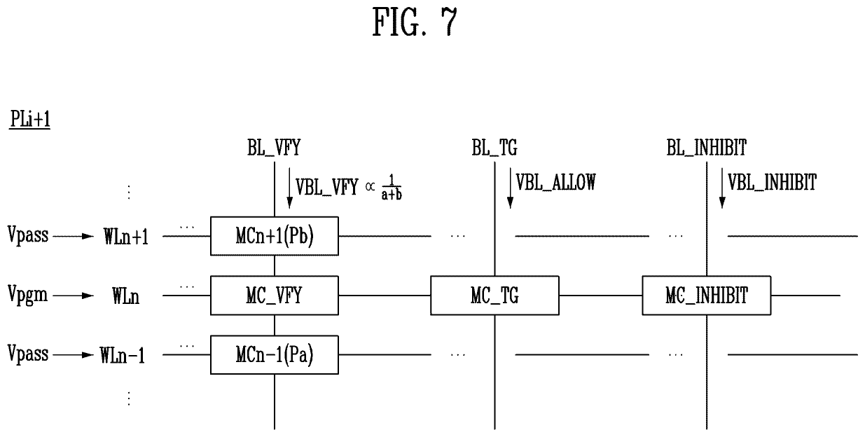

FIG. 7 is a diagram for describing bit line voltages to which bit lines are precharged during an over-program operation according to an embodiment of the present disclosure. In detail, FIG. 7 is a diagram for describing voltages to which bit lines are precharged during a program voltage apply operation (PGM Operation) in the (i+1)-th program loop PLi+1 illustrated in FIG. 6.

Referring to FIG. 7, the control logic 130 may control the peripheral circuit 120 to apply a program voltage Vpgm to a selected word line WLn after bit lines are precharged depending on the states of memory cells connected to respective bit lines.

For example, the peripheral circuit 120 may precharge a bit line BL_TG connected to a target memory cell MC_TG to a program-enable voltage VBL_ALLOW. Here, the target memory cell MC_TG may be a memory cell having failed in the verify operation (VFY Operation) in the i-th program loop PLi. In an embodiment, the program-enable voltage VBL_ALLOW may be a ground voltage. Further, the peripheral circuit 120 may precharge a bit line BL_INHIBIT connected to a program-inhibit cell MC_INHIBIT to a program-inhibit voltage VBL_INHIBIT. Here, the program-inhibit cell MC_INHIBIT may be a memory cell on which the over-program operation has been completed in the i-th program loop PLi. In an embodiment, the program-inhibit voltage VBL_INHIBIT may be a supply voltage.

In an embodiment, the control logic 130 may determine a bit line voltage VBL_VFY to which bit lines BL_VFY connected to memory cells MC_VFY having succeeded in the verify operation are to be precharged, based on the threshold voltages Pa and Pb of memory cells MCn−1 and MCn+1 connected to one or more word lines WLn−1 and WLn+1 adjacent to the selected word line WLn.

In an embodiment, the control logic 130 may obtain information on the threshold voltages Pa and Pb of the adjacent memory cells MCn−1 and MCn+1, based on at least one of a foggy program operation and a fine program operation, each including a program voltage apply operation and a verify operation performed on the adjacent memory cells MCn−1 and MCn+1. As described above with reference to FIG. 4, after the foggy program operation or the fine program operation is performed on the memory cells MCn−1 connected to the (n−1)-th word line WLn−1, the fine program operation may be performed on the selected memory cells connected to the selected word line WLn. Therefore, the control logic 130 may obtain information on the threshold voltage Pa of the memory cells MCn−1 connected to the (n−1)-th word line WLn−1 at a time point at which the fine program operation is performed on the selected memory cells. Further, after the foggy program operation is performed on the memory cells MCn+1 connected to the (n+1)-th word line WLn+1, the fine program operation may be performed on the selected memory cells connected to the selected word line WLn. Therefore, the control logic 130 may obtain information on the threshold voltage Pb of the memory cells MCn+1 connected to the (n+1)-th word line WLn+1 at a time point at which the fine program operation is performed on the selected memory cells.

In an embodiment, during a verify operation included in at least one of the foggy program operation and the fine program operation performed on the memory cells MCn−1 and MCn+1 connected to the one or more adjacent word lines WLn−1 and WLn+1, the control logic 130 may obtain information on the threshold voltages of the memory cells MCn−1 and MCn+1 based on the verify voltage applied to the one or more adjacent word lines WLn−1 and WLn+1. For example, during the verify operation included in the foggy program operation or the fine program operation performed on the memory cells MCn−1 connected to the (n−1)-th word line WLn−1, the control logic 130 may obtain information on the verify voltage applied to the memory cells MCn−1 connected to the (n−1)-th word line WLn−1. Therefore, the control logic 130 may obtain information on the threshold voltage Pa of the memory cells MCn−1 connected to the (n−1)-th word line WLn−1 based on the information on the verify voltage applied to the memory cells MCn−1 connected to the (n−1)-th word line WLn−1. Furthermore, during the verify operation included in the foggy program operation performed on the adjacent memory cells MCn+1 connected to the (n+1)-th word line WLn+1, the control logic 130 may obtain information on the verify voltage applied to the memory cells MCn+1 connected to the (n+1)-th word line WLn+1. Therefore, the control logic 130 may obtain information on the threshold voltage Pb of the memory cells MCn+1 connected to the (n+1)-th word line WLn+1 based on the information on the verify voltage applied to the memory cells MCn+1 connected to the (n+1)-th word line WLn+1.

In an embodiment, the control logic 130 may determine the bit line voltage VBL_VFY to be lowered as the threshold voltages Pa and Pb of the memory cells MCn−1 and MCn+1 connected to the one or more adjacent word lines WLn−1 and WLn+1 are lower. Also, the control logic 130 may determine the bit line voltage VBL_VFY based on the average value of the threshold voltages Pa and Pb of the memory cells MCn−1 and MCn+1 connected to the one or more adjacent word lines WLn−1 and WLn+1. For example, the control logic 130 may calculate (i.e., determine) the average value of the threshold voltages Pa and Pb of the memory cells MCn−1 and MCn+1. The control logic 130 may determine the bit line voltage VBL_VFY to be lowered as the average value of the threshold voltages Pa and Pb of the memory cells MCn−1 and MCn+1 is lower. That is, the bit line voltage VBL_VFY may be in inverse proportion to the average value of the threshold voltages Pa and Pb of the memory cells MCn−1 and MCn+1 connected to the one or more adjacent word lines WLn−1 and WLn+1.

In an embodiment, the bit line voltage VBL_VFY to which the bit lines BL_VFY connected to the memory cells MC_VFY having succeeded in the verify operation are precharged may be equal to or higher than the program-enable voltage VBL_ALLOW. Further, the bit line voltage VBL_VFY to which the bit lines BL_VFY connected to the memory cells MC_VFY having succeeded in the verify operation are precharged may be lower than the program-inhibit voltage VBL_INHIBIT.

Furthermore, the control logic 130 may control the peripheral circuit 120 to precharge the bit lines BL_VFY connected to the memory cells MC_VFY having succeeded in the verify operation to the determined bit line voltage VBL_VFY.

In an embodiment, the control logic 130 may control the peripheral circuit 120 to increase the threshold voltages of selected memory cells after the bit lines BL_VFY are precharged by the determined bit line voltage VBL_VFY.

In an embodiment, the control logic 130 may control the peripheral circuit 120 to apply the increased program voltage Vpgm to the selected word line WLn to increase the program voltage according to a preset magnitude and increase the threshold voltages of the selected memory cells. Here, the preset magnitude may be equal to the magnitude of a unit voltage by which the program voltage is increased whenever the plurality of program loops are performed, or may be less than the magnitude of the unit voltage. In an example, the control logic 130 may control the peripheral circuit 120 to increase the program voltage used in the i-th program loop PLi by the magnitude of the unit voltage and apply the increased program voltage Vpgm to the selected word line WLn. In an example, the control logic 130 may control the peripheral circuit 120 to increase the program voltage used in the i-th program loop PLi by a magnitude less than the magnitude of the unit voltage and apply the increased program voltage Vpgm to the selected word line WLn.

Furthermore, the control logic 130 may control the peripheral circuit 120 to apply the pass voltage Vpass to the one or more adjacent word lines WLn−1 and WLn+1.

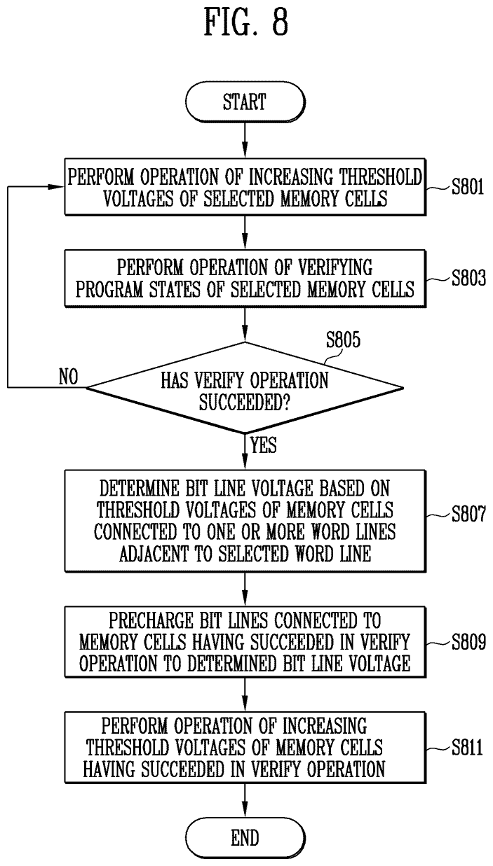

FIG. 8 is a flowchart illustrating a method of operating a memory device according to an embodiment of the present disclosure. The method illustrated in FIG. 8 may be performed by, for example, the memory device 100 illustrated in FIG. 1.

Referring to FIG. 8, at operation S801, the memory device 100 may perform an operation of increasing threshold voltages of selected memory cells connected to a selected word line, among a plurality of memory cells.

At operation S803, the memory device 100 may perform an operation of verifying the program states of the selected memory cells based on the increased threshold voltages.

At operation S805, the memory device 100 may determine whether the operation of verifying the program states of the selected memory cells has succeeded.

When it is determined that the operation of verifying the program states of the selected memory cells has succeeded (‘YES’ in the operation S805), the memory device 100 may perform operation S807. On the other hand, when it is determined that the operation of verifying the program states of the selected memory cells has failed (‘NO’ in the operation S805), the memory device 100 may re-perform operations S801 and S803 by increasing a program voltage by a unit voltage.

At the operation S807, the memory device 100 may determine a bit line voltage by which bit lines connected to the memory cells having succeeded in the verify operation, among a plurality of bit lines are to be precharged, based on the threshold voltages of memory cells connected to one or more word lines adjacent to the selected word line, among the plurality of memory cells.

For example, the memory device 100 may calculate (i.e., determine) the average value of the threshold voltages of the memory cells connected to the one or more adjacent word lines. The memory device 100 may determine the bit line voltage based on the average value of the threshold voltages of the memory cells connected to the one or more adjacent word lines. In this case, the memory device 100 may determine the bit line voltage to be lowered as the average value of the threshold voltages of the memory cells connected to the one or more adjacent word lines is lower.

At operation S809, the memory device 100 may precharge the bit lines connected to the memory cells having succeeded in the verify operation to the determined bit line voltage.

At operation S811, the memory device 100 may perform an operation of increasing the threshold voltages of the memory cells having succeeded in the verify operation.

According to the present disclosure, there are provided a memory device and a method of operating the memory device, which can improve reliability.

While embodiments of the present disclosure have been shown and described with reference to certain embodiments thereof, it will be understood by those skilled in the art that various changes in form and details may be made therein without departing from the spirit and scope of the present disclosure as defined by the appended claims and their equivalents. Therefore, the scope of the present disclosure should not be limited to the above-described embodiments but should be determined by not only the appended claims but also the equivalents thereof.

In the above-described embodiments, all operations may be selectively performed or part of the operations may be omitted. In each embodiment, the operations are not necessarily performed in accordance with the described order and may be rearranged. The embodiments disclosed in this specification and drawings are only examples to facilitate an understanding of the present disclosure, and the embodiments of the present disclosure are not limited thereto. That is, it should be apparent to those skilled in the art that various modifications can be made based on the technological scope of the present disclosure.

The embodiments of the present disclosure have been described in the drawings and specification. Although specific terminologies are used here, those are only to describe the embodiments of the present disclosure. Therefore, the embodiments of the present disclosure are not restricted to the above-described embodiments and many variations are possible within the spirit and scope of the present disclosure. It should be apparent to those skilled in the art that various modifications can be made based on the technological scope of the present disclosure in addition to the embodiments disclosed herein. Furthermore, the embodiments may be combined to form additional embodiments.

What is claimed is:

1. A memory device comprising:
a memory cell array including a plurality of memory cells connected to a plurality of word lines and a plurality of bit lines;
a peripheral circuit configured to perform a first program voltage apply operation of increasing threshold voltages of selected memory cells connected to a selected word line, among the plurality of memory cells and a verify operation of verifying program states of the selected memory cells based on the increased threshold voltages; and
a control logic configured to, after the verify operation performed on at least one of the selected memory cells has succeeded, control the peripheral circuit to
determine, based on threshold voltages of memory cells connected to one or more word lines adjacent to the selected word line, among the plurality of memory cells, a bit line voltage by which a bit line connected to the memory cell having succeeded in the verify operation, among the plurality of bit lines is to be precharged, and
perform a second program voltage apply operation of increasing a threshold voltage of the memory cell having succeeded in the verify operation based on the determined bit line voltage.

2. The memory device according to claim 1, wherein the control logic is configured to control the peripheral circuit to, after the bit line connected to the memory cell having succeeded in the verify operation has been precharged by the determined bit line voltage, perform the second program voltage apply operation.

3. The memory device according to claim 2, wherein the control logic is configured to determine the bit line voltage to be lowered as the threshold voltages of the memory cells connected to the one or more adjacent word lines are lower.

4. The memory device according to claim 2, wherein the control logic is configured to determine the bit line voltage based on an average value of the threshold voltages of the memory cells connected to the one or more adjacent word lines.

5. The memory device according to claim 1, wherein the peripheral circuit is configured to, after performing a third program voltage apply operation of increasing the threshold voltages of the memory cells connected to the one or more adjacent word lines and the verify operation, perform the first program voltage apply operation, the verify operation, and the second program voltage apply operation on the selected memory cells.

6. The memory device according to claim 5, wherein the control logic is configured to, during the verify operation performed on the memory cells connected to the one or more adjacent word lines, obtain information on the threshold voltages of the memory cells connected to the one or more adjacent word lines based on a verify voltage applied to the one or more adjacent word lines.

7. The memory device according to claim 5, wherein:
the third program voltage apply operation and the verify operation performed on the memory cells connected to the one or more adjacent word lines are included in at least one of a foggy program operation performed on the memory cells connected to the one or more adjacent word lines and a fine program operation performed after the foggy program operation; and
the first program voltage apply operation, the verify operation, and the second program voltage apply operation performed on the selected memory cells are included in the fine program operation performed on the selected memory cells.

8. A method of operating a memory device including a plurality of memory cells connected to a plurality of word lines and a plurality of bit lines, the method comprising;
increasing threshold voltages of selected memory cells connected to a selected word line, among the plurality of memory cells;
verifying program states of the selected memory cells based on the increased threshold voltages;
determining, in response to a determination that an operation of verifying the program state of at least one of the selected memory cells has succeeded, a bit line voltage by which a bit line connected to the memory cell having succeeded in the verify operation, among the plurality of bit lines is to be precharged, based on threshold voltages of memory cells connected to one or more word lines adjacent to the selected word line among the plurality of memory cells;
precharging the bit line connected to the memory cell having succeeded in the verify operation to the determined bit line voltage; and
increasing a threshold voltage of the memory cell having succeeded in the verify operation.

9. The method according to claim 8, wherein determining the bit line voltage comprises:
calculating an average value of the threshold voltages of the memory cells connected to the one or more adjacent word lines; and
determining the bit line voltage based on the average value.

10. The method according to claim 9, wherein determining the bit line voltage comprises:
determining the bit line voltage to be lowered as the average value is lower.

11. The method according to claim 8, further comprising, before increasing the threshold voltages of the selected memory cells:
verifying program states of the memory cells connected to the one or more adjacent word lines; and
obtaining, in response to a determination that an operation of verifying the program states of the memory cells connected to the one or more adjacent word lines has succeeded, information on the threshold voltages of the memory cells connected to the one or more adjacent word lines, based on a verify voltage applied to the one or more adjacent word lines during the operation of verifying the program states of the memory cells connected to the one or more adjacent word lines.

12. A memory device comprising:
a memory cell array including a plurality of memory cells connected to a plurality of word lines and a plurality of bit lines;
a peripheral circuit configured to perform a first program operation including a plurality of program loops, each of the plurality of program loop including a program voltage apply operation of increasing threshold voltages of selected memory cells connected to a selected word line, among the plurality of memory cells and a verify operation of verifying program states of the selected memory cells based on the increased threshold voltages; and
a control logic configured to, when the verify operation performed on at least one of the selected memory cells has succeeded in a first program loop among the plurality of program loops, control the peripheral circuit to
determine a bit line voltage by which a bit line connected to the memory cell having succeeded in the verify operation included in the first program loop, among the plurality of bit lines is to be precharged, based on threshold voltages of memory cells connected to one or more word lines adjacent to the selected word line among the plurality of memory cells in a second program loop performed after the first program loop among the plurality of program loops, and
perform the program voltage apply operation of increasing a threshold voltage of the memory cell having succeeded in the verify operation included in the first program loop based on the determined bit line voltage.

13. The memory device according to claim 12, wherein the control logic is configured to control the peripheral circuit to perform the program voltage apply operation of increasing the threshold voltage of the memory cell having succeeded in the verify operation after the bit line connected to the memory cell having succeeded in the verify operation included in the first program loop has been precharged by the determined bit line voltage.

14. The memory device according to claim 13, wherein the control logic is configured to determine the bit line voltage to be lowered as the threshold voltages of the memory cells connected to the one or more adjacent word lines are lower.

15. The memory device according to claim 12, wherein the peripheral circuit is configured to perform the first program operation on the selected memory cells after performing a second program operation including the plurality of program loops on the memory cells connected to the one or more adjacent word lines.

16. The memory device according to claim 15, wherein the peripheral circuit is configured to, during a verify operation included in the second program operation performed on the memory cells connected to the one or more adjacent word lines, obtain information on the threshold voltages of the memory cells connected to the one or more adjacent word lines, based on a verify voltage applied to the one or more adjacent word lines.
